(19) United States
(12) Patent Application Publication
(10) Pub. No.: US 2016/0020122 A1
(43) Pub. Date: Jan. 21, 2016

(54) SUBSTRATE PROCESSING APPARATUS AND SUBSTRATE PROCESSING METHOD

(71) Applicant: Tokyo Electron Limited, Tokyo (JP)

(72) Inventors: Sho Watanabe, Kumamoto (JP); Daisuke Aoki, Kumamoto (JP); Tooru Nakamura, Kumamoto (JP)

(21) Appl. No.: 14/795,316

(22) Filed: Jul. 9, 2015

(30) Foreign Application Priority Data
Jul. 15, 2014 (JP) 2014-145264

(51) Int. Cl. H01L 21/67

(52) U.S. Cl. CPC H01L 21/67023; H01L 21/67253

(57) ABSTRACT

A substrate processing apparatus includes: a chamber that accommodates a processing target substrate therein; a gas supply unit that supplies a gas into the chamber; a gas discharge port that exhausts the chamber; an adjustment mechanism that adjusts an exhaust amount discharged from the gas discharge port; a measuring unit that measures an internal pressure of the chamber; and a controller that executes a series of substrate processings according to recipe information indicating contents of substrate processings. The controller performs a feedback control that controls an opening degree of the adjustment mechanism to maintain the internal pressure within a prescribed range based on a measurement result from the measuring unit. When a predetermined event, estimated to change the internal pressure to a level out of the prescribed range, occurs, the controller switches the feedback control to a non-feedback control that controls the opening degree based on a prescribed control value.

### CROSS-REFERENCE TO RELATED APPLICATIONS

This application is based on and claims priority from Japanese Patent Application No. 2014-145264, filed on Jul. 15, 2014, with the Japan Patent Office, the disclosure of which is incorporated herein in its entirety by reference.

### TECHNICAL FIELD

Exemplary embodiments disclosed herein are related to a substrate processing apparatus and a substrate processing method.

### BACKGROUND

In a conventional substrate processing apparatus, a series of substrate processings, such as, for example, a chemical liquid processing for supplying a chemical liquid such as, for example, a diluted hydrofluoric (DHF) acid so as to process the surface of a substrate, and a rinsing process for supplying a rinse liquid such as, for example, a de-ionized water (DIW) so as to rinse out the chemical liquid from the substrate, are performed on a substrate such as, for example, a semiconductor wafer or a glass substrate according to a predetermined recipe.

During such substrate processings, the substrate is placed within a chamber. In order to prevent, for example, particles from adhering to the substrate, a clean air flow is generated in the chamber and the internal pressure of the chamber is controlled to be maintained substantially constant.

As a technology for maintaining the internal pressure of the chamber constant, it has been known to provide a detection means for detecting a pressure difference between the inside and the outside of the chamber, and then to properly perform a feedback control on the supplied amount of clean air flow based on a change in the pressure difference detected by the detection means (see, e.g., Japanese Patent Laid-Open Publication No. H11-111664).

### SUMMARY

According to an aspect of the present disclosure, a substrate processing apparatus includes: a chamber configured to accommodate a processing target substrate therein; a gas supply unit configured to supply a gas into the chamber; a gas discharge port configured to exhaust the chamber; an adjustment mechanism configured to adjust an exhaust amount discharged from the gas discharge port; a measuring unit configured to measure an internal pressure of the chamber; and a controller configured to execute a series of substrate processings according to recipe information indicating contents of substrate processings. The controller performs a feedback control that controls an opening degree of the adjustment mechanism to maintain the internal pressure within a prescribed range based on a measurement result from the measuring unit, and, when a predetermined event, estimated to change the internal pressure to a level out of the prescribed range, occurs, the controller switches the feedback control to a non-feedback control that controls the opening degree based on a prescribed control value.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a configuration of a substrate processing system according to the present exemplary embodiment.

FIG. 2 is a view schematically illustrating a configuration of a processing unit.

FIG. 3 is a schematic view illustrating an example of a specific configuration of the processing unit.

FIG. 4 is a block diagram of a control device.

FIG. 5 is a flowchart illustrating a processing order of a series of substrate processings executed in the processing unit.

FIG. 6A is an explanatory view (Part 1) for describing a case in which the controller functions as a switching unit.

FIG. 6B is an explanatory view (Part 2) for describing a case where the controller functions as a switching unit.

FIG. 7 is a table representing an example of control value information.

FIG. 8A is a view illustrating a change in pressure and opening in a conventional feedback control.

FIG. 8B illustrates an example of a feedback control executed by the controller.

FIG. 9A is an explanatory view (Part 1) illustrating a case in which the controller controls an opening degree step by step.

FIG. 9B is an explanatory view (Part 2) illustrating a case in which the controller controls an opening degree step by step.

FIG. 9C is an explanatory view (Part 3) illustrating a case in which the controller controls an opening degree step by step.

FIG. 10A is an explanatory view illustrating a case in which the controller starting of control of the opening degree.

FIG. 10B is an explanatory view illustrating a case in which the controller advances starting of control of the opening degree.

FIG. 11 is a flowchart illustrating a processing order of processings executed when the controller functions as a damper adjustment unit.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

The technology disclosed in Japanese Patent Laid-Open Publication No. 11-111664 needs to be further improved so as to properly maintain the internal pressure of the chamber.

The technology disclosed in Japanese Patent Laid-Open Publication No. 11-111664 maintains the internal pressure of the chamber by a normal feedback control. However, for example, in a case where a clean air flow supply path is switched according to each of the substrate processings, it may become impossible to handle a sharp change in the internal pressure caused by the switching of the air flow supply path.

One aspect of an exemplary embodiment is to provide a substrate processing apparatus and a substrate processing method capable of properly maintaining the internal pressure of the chamber.

According to one aspect of an exemplary embodiment, a substrate processing apparatus includes: a chamber configured to accommodate a processing target substrate therein; a gas supply unit configured to supply a gas into the chamber; a gas discharge port configured to exhaust the chamber; an adjustment mechanism configured to adjust an exhaust amount discharged from the gas discharge port; a measuring unit configured to measure an internal pressure of the chamber; and a controller configured to execute a series of substrate processings according to recipe information indicating contents of substrate processings. The controller performs a feedback control that controls an opening degree of the adjustment mechanism to maintain the internal pressure within a prescribed range based on a measurement result from the measuring unit, and, when a predetermined event, estimated to change the internal pressure to a level out of the prescribed range, occurs, the controller switches the feedback control to a non-feedback control that controls the opening degree based on a prescribed control value.

In the substrate processing apparatus described above, the controller performs the non-feedback control when an event, estimated to change the internal pressure to a negative pressure out of the prescribed range, occurs.

In the substrate processing apparatus described above, the series of substrate processings include a chemical liquid processing for supplying a chemical liquid to the substrate, a rinsing process for supplying a rinse liquid to the substrate after the chemical liquid processing, and a drying process for drying the substrate after rinsing process. The gas supply unit further includes: a first gas supply unit configured to supply a first gas; and a second gas supply unit configured to supply a second gas at the drying process. When switching from the first gas supply unit to the second gas supply unit is executed, the controller switches the feedback control to the non-feedback control.

In the substrate processing apparatus described above, the series of substrate processings include a chemical liquid processing for supplying a chemical liquid to the substrate, a rinsing process for supplying a rinse liquid after the chemical liquid processing, and a drying process for drying the substrate after the rinsing process, the gas discharge port connects gas discharge paths of a plurality of systems according to respective processings in the substrate processings, and the controller switches the feedback control to the non-feedback control when switching between the gas discharge paths is executed at the time of transition of each processing of the substrate processings.

In the substrate processing apparatus described above, the gas discharge paths include a first gas discharge path in the rinsing process and a second gas discharge path in the drying process.

In the substrate processing apparatus described above, the series of substrate processings include a chemical liquid processing for supplying a chemical liquid to the substrate, a rinsing process for supplying a rinse liquid after the chemical liquid processing, and a drying process for drying the substrate after the rinsing process. The substrate processing apparatus further includes a substrate holding mechanism placed within the chamber and configured to hold and rotate the substrate; and a plurality of recovery cups arranged concentrically to a rotation center of the substrate rotated by the substrate holding mechanism and configured to recover discharged liquid in the respective processings of the substrate processings. When switching between the recovery cups is executed at the time of transition of each respective processing of the substrate processings, the controller switches the feedback control to the non-feedback control.

In the substrate processing apparatus described above, the recovery cups include a first recovery cup configured to recover discharged liquid in the rinsing process and a second recovery cup configured to recover discharged liquid in the drying process.

In the substrate processing apparatus described above, the control value includes a control value of a maintained time indicating a time for maintaining the opening degree, and the controller maintains the opening degree based on the control value of the maintained time.

In the substrate processing apparatus described above, when the maintained time lapses, the controller returns the control of the opening degree from the non-feedback control to the feedback control.

In the substrate processing apparatus described above described above, the control value includes a step designation control value for changing the opening degree and the maintained time step by step, and the controller changes the opening degree and the maintained time step by step based on the step designation control value.

In the substrate processing apparatus described above, the control value includes a control value of a delayed time indicating a time for delaying starting of control of the opening degree, and the controller delays the starting of control of the opening degree based on the control value of the delayed time.

In the substrate processing apparatus described above, the control value includes a control value of an advanced time indicating a time for advancing the starting of control of the opening degree, and the controller advances the starting of control of the opening based on the control value of the preceding time.

According to an aspect of another exemplary embodiment, a substrate processing method includes: a control process for executing a series of substrate processings according to recipe information indicating contents of substrate processings using a substrate processing apparatus including a chamber configured to accommodate a processing target substrate, a gas supply unit configured to supply a gas into the chamber, a gas discharge port configured to exhaust the chamber, an adjustment mechanism configured to control an exhaust amount discharged through the gas discharge port, and a measuring unit configured to measure an internal pressure of the chamber. The control process executes a feedback control that controls an opening degree of the adjustment mechanism to maintain the internal pressure within a prescribed range based on a measurement result from the measuring unit; and, when a predetermined event, estimated to change the internal pressure to a level out of the prescribed range, occurs, the control process switches the feedback control to a non-feedback control that controls the opening degree based on a prescribed control value.

According to one aspect of an exemplary embodiment, the internal pressure of the chamber is capable of being maintained properly.

In the following, the exemplary embodiments of the substrate processing apparatus and the substrate processing method according to the present disclosure will be described in detail with reference to the accompanying drawings. However, the present disclosure is not limited to the exemplary embodiments described below.

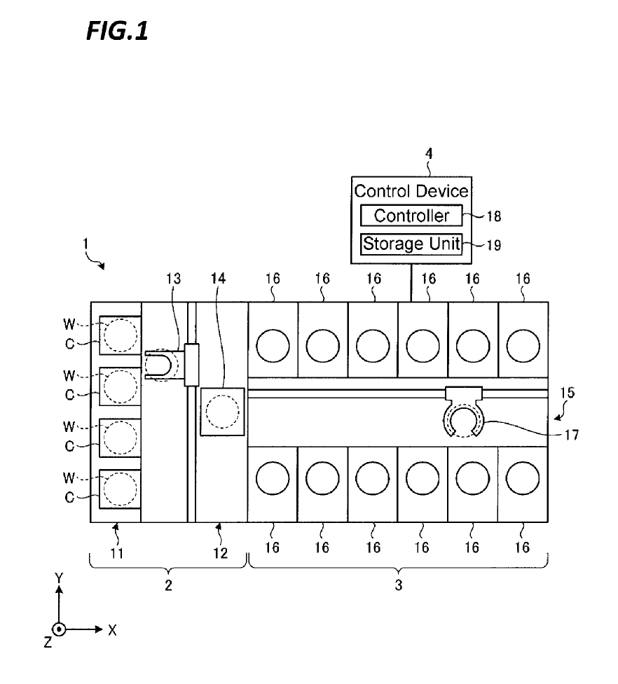

FIG. 1 is a plan view illustrating an outline of a substrate processing system provided with a processing unit according to an exemplary embodiment of the present disclosure. In the following, in order to clarify positional relationships, the X-axis, Y-axis and Z-axis which are orthogonal to each other will be defined. The positive Z-axis direction will be regarded as a vertically upward direction.

As illustrated in FIG. 1, a substrate processing system 1 includes a carry-in/out station 2 and a processing station 3. The carry-in/out station 2 and a processing station 3 are provided adjacent to each other.

The carry-in/out station 2 is provided with a carrier placing section 11 and a transfer section 12. In the carrier placing section 11, a plurality of carriers C is placed to accommodate a plurality of substrates (semiconductor wafers in the present exemplary embodiment) (hereinafter, referred to as “wafers W”) horizontally.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafers W between the carriers C and the delivery unit 14 by using the wafer holding mechanism.

The processing station 3 is provided adjacent to the transfer section 12. The processing station 3 is provided with a transfer section 15 and a plurality of processing units 16. The plurality of processing units 16 is arranged at both sides of the transfer section 15.

The transfer section 15 is provided with a substrate transfer device 17 therein. The substrate transfer device 17 is provided with a wafer holding mechanism configured to hold the wafer W. Further, the substrate transfer device 17 is movable horizontally and vertically and pivotable around a vertical axis. The substrate transfer device 17 transfers the wafers W between the delivery unit 14 and the processing units 16 by using the wafer holding mechanism.

The processing units 16 perform a predetermined substrate processing on the wafers W transferred by the substrate transfer device 17.

Further, the liquid processing system 1 is provided with a control device 4. The control device 4 is, for example, a computer, and includes a controller 18 and a storage unit 19. The storage unit 19 stores a program that controls various processings performed in the liquid processing system 1. The controller 18 controls the operations of the liquid processing system 1 by reading and executing the program stored in the storage unit 19.

Further, the program may be recorded in a computer-readable recording medium, and installed from the recording medium to the storage unit 19 of the control device 4. The computer-readable recording medium may be, for example, a hard disc (HD), a flexible disc (FD), a compact disc (CD), a magnet optical disc (MO), or a memory card.

In the substrate processing system 1 configured as described above, the substrate transfer device 13 of the carry-in/out station 2 first takes out a wafer W from a carrier C placed in the carrier placing section 11, and then places the taken wafer W on the transfer unit 14. The wafer W placed on the transfer unit 14 is taken out from the transfer unit 14 by the substrate transfer device 17 of the processing station 3 and carried into a processing unit 16.

The wafer W carried into the processing unit 16 is processed by the processing unit 16, and then, carried out from the processing unit 16 and placed on the delivery unit 14 by the substrate transfer device 17. After the processing of placing the wafer W on the delivery unit 14, the wafer W returns to the carrier C of the carrier placing section 11 by the substrate transfer device 13.

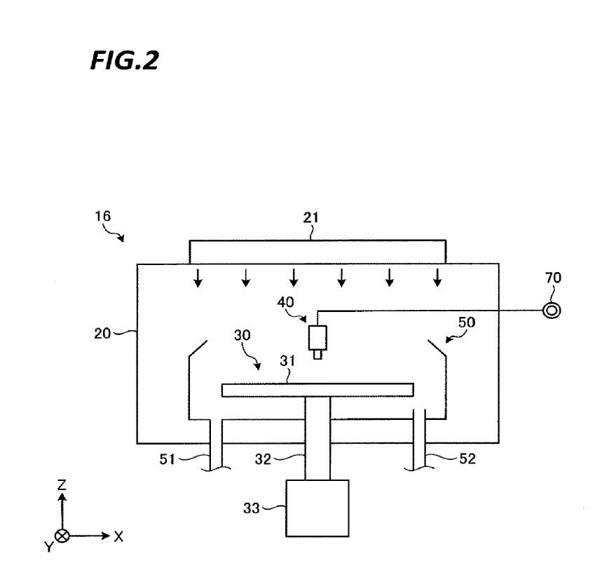

Next, a schematic configuration of the processing unit 16 will be described with reference to FIG. 2. FIG. 2 is a view illustrating a schematic configuration of the processing unit 16.

As illustrated in FIG. 2, the processing unit 16 is provided with a chamber 20, a substrate holding mechanism 30, a processing fluid supply unit 40, and a recovery cup 50.

The chamber 20 accommodates the substrate holding mechanism 30, the processing fluid supply unit 40, and the recovery cup 50. A fan filter unit (FFU) 21 is provided on the ceiling of the chamber 20. The FFU 21 forms a downflow in the chamber 20.

The substrate holding mechanism 30 is provided with a holding unit 31, a support unit 32, and a driving unit 33. The holding unit 31 holds the wafer W horizontally. The support unit 32 is a vertically extending member, and has a base end portion supported rotatably by the driving unit 33 and a tip end portion supporting the holding unit 31 horizontally. The driving unit 33 rotates the support unit 32 around the vertical axis. The substrate holding mechanism 30 rotates the support unit 32 by using the driving unit 33, so that the holding unit 31 supported by the support unit 32 is rotated, and hence, the wafer W held in the holding unit 31 is rotated. The processing fluid supply unit 40 supplies a processing fluid onto the wafer W.

The processing fluid supply unit 40 is connected to a processing fluid source 70.

The recovery cup 50 is disposed to surround the holding unit 31, and collects the processing liquid scattered from the wafer W by the rotation of the holding unit 31. A liquid discharge port 51 is formed on the bottom of the recovery cup 50, and the processing liquid collected by the recovery cup 50 is discharged from the liquid discharge port 51 to the outside of the processing unit 16. Further, a gas discharge port 52 is formed on the bottom of the recovery cup 50 to discharge a gas supplied from the FFU 21 to the outside.

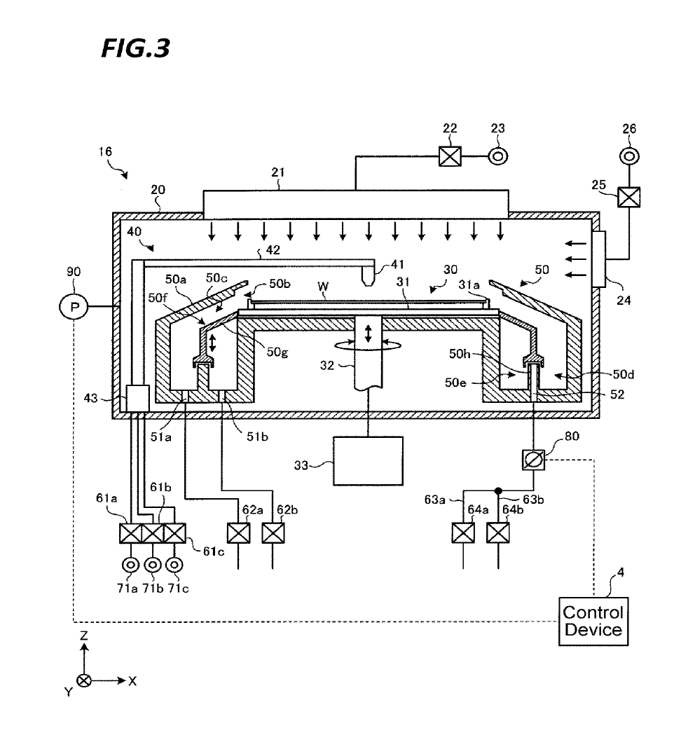

Next, the configuration of the processing unit 16 will be described in more detail with reference to FIG. 3. FIG. 3 is a schematic view illustrating an example of a specific configuration of the processing unit 16.

As illustrated in FIG. 3, an inert gas supply source 23 is connected to the FFU 21 via a valve 22. The FFU 21 feeds an inert gas supplied from the inert gas supply source 23 such as, for example, N₂ gas, to the chamber 20. The FFU 21 may also feed the air purified by an ultra-low penetration air (ULPA) filter to the chamber 20.

Also, the processing unit 16 is further provided with a clean dry air (CDA) supply unit 24 on a sidewall of the chamber 20. To the CDA supply unit 24, a CDA supply source 26 is connected via a valve 25. The CDA supply unit 24 feeds the CDA supplied from the CDA supply source 26 to the inside of the chamber 20.

Further, in the processing unit 16, gas supply to the inside of the chamber 20 is switched from the gas supply via the FFU 21 to the gas supply via the CDA supply unit 24 at the time of transition from the rinsing process to the drying process. The transition will be described later. Hereinafter, such switching may be referred to as “gas supply switching.”

Also, the holding unit 31 of the substrate holding mechanism 30 includes a holding member 31 provided on the top surface thereof so as to hold a wafer W from the lateral side. The wafer W is horizontally held by the holding member 31a in a state where the wafer W is slightly spaced apart from the top surface of the holding unit 31.

The processing fluid supply unit 40 is provided with a nozzle 41, an arm 42 configured to support the nozzle horizontally, and a rotatable lifting mechanism 43 configured to rotate and move up and down the arm 42.

In a chemical liquid processing to be described later, the processing fluid supply unit 40 supplies DHF, which is a kind of chemical liquid, to the wafer W through the nozzle 41. In addition, in a rinsing process to be described later, the processing fluid supply unit 40 supplies DIW, which is a kind of rinse liquid, to the wafer W through the nozzle 41.

In a drying process to be described hereinafter, the processing fluid supply unit 40 also supplies isopropyl alcohol (IPA), which is a kind of organic solvent, to the wafer W through the nozzle 41.

The DHF is supplied from a DHF supply source 71a via a valve 61a, the DIW is supplied from a DIW supply source 71b via valve 61b, and the IPA is supplied from an IPA supply source 71c via a valve 61c.

In the drying process, an inert gas such as, for example, N₂ gas, may be used in combination, in which the N₂ gas may be supplied through the nozzle 41.

The recovery cup 50 may be provided as a multistage configuration concentrically arranged on the rotation center of the wafer W held and rotated by the substrate holding mechanism 30. Specifically, the recovery cup 50 includes a first recovery cup 50a and a second recovery cup 50f.

The first recover cup 50a has a shape that surrounds the lower side of the bottom surface and the outside of the outer periphery of the wafer W and opens the top side of the wafer W. The first recovery cup 50a forms a recovery port 50b at the outside of the outer periphery of the wafer W, and forms a recovery space 50c communicating with the recovery port 50b at the lower side.

Also, the first recovery cup 50a forms a ring-like partition wall 50h concentric to the bottom portion of the recovery space 50c so as to divide the bottom portion of the recovery space 50c into a first recovery portion 50d and a second recovery portion 50e in a concentric dual ring shape. In the respective bottom portions of the first recovery portion 50d and the second recovery portion 50e, liquid discharge ports 51a, 51b are formed to be spaced apart from each other along the circumferential direction of the recovery cup 50.

The discharge path from the liquid discharge port 51a is connected to a valve 62a. The liquid discharged through the liquid discharge port 51a (e.g., an organic processing fluid such as IPA) is discharged from the processing unit 16 to the outside via the valve 62a.

The discharge path from the liquid discharge port 51b is connected to a valve 62b. The liquid discharged through the liquid discharge port 51b (e.g., an acidic processing liquid such as DHF) is discharged from the processing unit 16 to the outside via the valve 62b. Meanwhile, the valve 62b may be provided in the form of a plurality of valves that may be individually divided depending on the nature of a processing liquid, such as whether the processing liquid is an acidic or an alkaline liquid, thereby branching the discharge path. Also, in the case where the processing liquid is reusable, the processing liquid discharged via the valve 62b may be recovered.

In the partition wall 50h of the first recovery cup 50a, a plurality of gas discharge ports 52 are formed to be spaced apart from each other along the circumferential direction of the partition wall, in which the gas discharge ports 52 penetrate the partition wall 50h and are opened at a level higher than the liquid discharge ports 51a, 51b in the recovery cup 50.

The second recovery cup 50f is liftably mounted just above the partition wall 50h with a predetermined gap therebetween. To the second recovery cup 50f, a lifting mechanism (not illustrated) is connected so as to move up and down the second recovery cup 50f. The lifting movement of the lifting mechanism is controlled by the control device 4.

The second recovery cup 50f is provided, on its top end, with an inclined wall portion 50g tilted inwards while extending upwardly to the recovery port 50b of the first recovery cup 50a. The inclined wall portion 50g extends to the recovery port 50b of the first recovery cup 50a in parallel to an inclined wall of the recovery space 50c. The inclined wall portion 50g is provided close to the inclined wall of the recovery space 50c of the first recovery cup 50a.

When the second recovery cup 50f is moved down by the lifting mechanism (not illustrated), a flow passage extending from the recovery port 50b to the liquid discharge port 51a of the first recovery portion 50d is defined between the inclined wall of the first recovery cup 50a and the inclined wall portion 50g of the second recovery cup 50f within the recovery space 50c.

When the second recovery cup 50f is moved up by the lifting mechanism (not illustrated), a flow passage extending from the recovery port 50b to the liquid discharge port 51b is defined in the inside of the inclined wall portion 50g of the second recovery cup 50f within the recovery space 50c.

Further, when performing a substrate processing, the processing unit 16 moves up and down the second recovery cup 50f depending on the type of the processing liquid used in each processing performed during the substrate processing, thereby performing the switching of the liquid discharge ports 51a, 51b.

For example, in the case where DHF, which is an acidic processing liquid, is ejected to the wafer W so as to process the wafer W, the control device 4 opens the valve 61a while rotating the holding unit 31 at a given rotating speed by controlling the driving unit 33. As a result, the DHF supplied from the DHF supply source 71a is ejected to the top surface of the wafer W through the nozzle 41.

At the same time, the control device 4 controls the above-described lifting mechanism to move up the second recovery cup 50f so as to form the flow passage extending from the recovery port 50b to the liquid discharge port 51b of the second recovery portion 50e.

By doing so, the DHF supplied to the wafer W is splashed toward the outside of the outer periphery of the wafer W by the centrifugal force generated due to the rotation of the wafer W, and is recovered by the second recovery portion 50e of the recovery space 50c through the recovery port 50b of the first recovery cup 50a. Then, the DHF is discharged through the liquid discharge port 51b.

Also, when an organic processing liquid, for example, IPA, is ejected to the wafer W so as to process the wafer W, the control device 4 opens the valve 61c while rotating the holding unit 31 at a given rotating speed by controlling the driving unit 33. As a result, the IPA supplied from the IPA supply source 71c is ejected to the top surface of the wafer W through the nozzle 41.

At the same time, the control device 4 controls the above-mentioned lifting mechanism to move down the second recovery cup 50f, thereby forming the flow passage extending from the recovery port 50b to the liquid discharge port 51a of the first recovery portion 50d.

By doing so, the IPA supplied to the wafer W is splashed towards the outside of the outer periphery of the wafer W by the centrifugal force generated due to the rotation of the wafer W, and is recovered by the first recovery portion 50d of the recovery space 50c through the recovery port 50b of the first recovery cup 50a. Then, the IPA is discharged through the liquid discharge port 51a.

The switching between the liquid discharge ports 51a, 51b, which is performed by moving up and down the second recovery cup 50f as described above, may also be referred to as “cup switching” in the following.

Also, the processing unit 16 is further provided with a damper 80. The gas discharge path extending from the gas discharge ports 52 formed in the partition wall 50h of the first recovery cup 50a is connected to the damper 80. The damper 80 is an adjustment mechanism configured to adjust the exhaust amount discharged through the gas discharge ports 52, and the opening degree thereof is controlled by the control device 4 so as to control the exhaust amount.

In the present exemplary embodiment, the opening degree of the damper 80 is controllable within a range from 0° to 90°, in which it is assumed that 0° indicates that the damper 80 is in the “completely opened” state and 90° indicates that the damper 80 is in the “completely closed” state.

The gas discharge path extending from the damper 80 is branched to multiple systems, for example, to a first gas discharge path 63a and a second gas discharge path 63b. The first gas discharge path 63a is connected to a valve 64a, and the second gas discharge path 63b is connected to a valve 64b.

The first gas discharge path 63a is an acidic gas discharge path, and the second gas discharge path 63b is an organic gas discharge path. These paths are switched by the control device 4 depending on each processing performed during the substrate processing.

For example, when a chemical liquid processing and a rinsing process, in which, for example, DHF mists may be contained in the discharged gas, are performed, switching to the first gas discharge path 63a is executed by the control device 4 so that the acidic gas is discharged via the valve 64a.

In addition, when a drying process, in which, for example, IPA mists may be contained in the discharged gas, is performed, switching to the second gas discharge path 63b is executed by the control device 4 so that the organic gas is discharged via the valve 64b.

The switching between the first gas discharge path 63a and the second gas discharge path 63b executed as described above may also be referred to as “gas discharge switching” in the following.

Also, the processing unit is further provided with a measuring unit 90. The measuring unit 90, for example, is disposed outside the chamber 20 so as to normally monitor and measure the internal pressure of the chamber 20 and notifies the control device 4 of a measurement result. The control device 4 generally performs a feedback control on the opening degree of the damper 80 based on the measurement result from the measuring unit 90 so that the internal pressure of the chamber 20 is maintained within a prescribed range.

In addition, the aforementioned prescribed range may be a little positive pressure so as to prevent, e.g., particles from adhering to the wafer W. The present exemplary embodiment will be further described below assuming that the prescribed range is about 0 Pa to about 2.5 Pa (Pascal).

However, when a predetermined event such as, for example, “gas supply switching,” “cup switching,” or “gas discharge switching” is performed during a substrate processing, a sharp change of the internal pressure may occur within the chamber 20 such that the feedback control cannot be performed. Specifically, the following cases may be considered:

(1) while a feedback (FB) signal has been outputted, the motion of the damper 80 cannot follow the FB signal;

(2) since the fluctuation of the internal pressure is excessively fast, the FB cannot follow the fluctuation; or

(3) since the fluctuation of the internal pressure is excessively fast, the internal pressure of the chamber 20 fluctuates and thereafter, the FB control is performed. The present exemplary embodiment will be described with reference to the case (1).

This case is undesirable because, when the chamber 20 remains in the negative pressure state for a predetermined period of time until the motion of the damper 80 follows, for example, adhesion of particles to the wafer W is caused. Thus, in the present exemplary embodiment, when a predetermined event as described above occurs, the control of the opening degree of the damper 80 is switched from a feedback control to a non-feedback control.

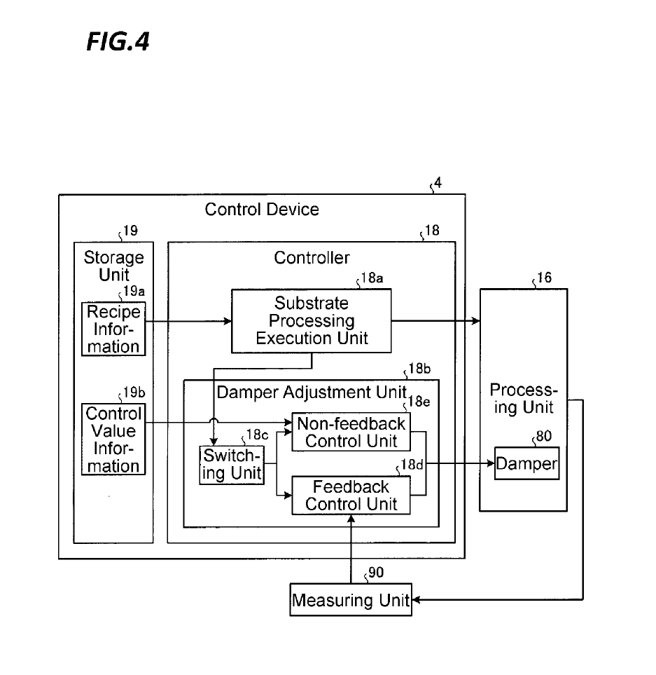

By doing so, even if a sharp change occurs in the internal pressure of the chamber 20, the internal pressure of the chamber 20 may be properly maintained. In addition, such switching from feedback control to non-feedback control is controlled by a controller 18 of the control device 4. Then, the control device 4 will be described in more detail with reference to FIG. 4.

FIG. 4 is a block diagram illustrating the control device 4. FIG. 4 illustrates elements required for describing the characteristics of the present exemplary embodiment using functional blocks, while illustration of general elements is omitted.

In other words, each element illustrated in FIG. 4 is represented in a functional sense, but does not necessarily have to be configured as represented in a physical sense. For example, a specific configuration of the distribution or integration of respective functional blocks is not limited to the illustrated configuration, and rather all or some of them may be configured by functional or physical distribution and integration in any unit according to various loads or use situations.

Also, each processing function executed in each functional block may be entirely or optionally partially implemented by a processor such as, for example, a central processing unit (CPU) and a program interpreted and executed in the processor, or implemented as a wired logic hardware.

First, as already described, the control device 4 is provided with the controller 18 and the storage unit 19 (see FIG. 1). The controller 18 is, for example, a CPU, and functions as, for example, respective functional blocks 18a to 18e illustrated in FIG. 4 by reading and executing a program (not illustrated) stored in the storage unit 19. Descriptions will be made on each of the functional blocks 18a to 18e.

As illustrated in FIG. 4, for example, the controller 18 is provided with a substrate processing execution unit 18a and a damper adjustment unit 18b. The damper adjustment unit 18b is provided with a switching unit 18c, a feedback controller 18d, and a non-feedback controller 18e. Also, the storage unit 19 stores recipe information 19a and control value information 19b.

When functioning as the substrate processing execution unit 18a, the controller 18 controls the processing unit 16 based on the recipe information 19a stored in the storage unit 19 to so as to execute a series of substrate processings, including a chemical liquid processing for supplying a chemical liquid to a wafer W, a rinsing process for supplying a rinse liquid to the wafer W, and a drying process for drying the wafer W.

The recipe information 19a indicates the contents of substrate processings. Specifically, the recipe information 19a is information in which the contents of respective processings to be executed by the processing unit 16 during the substrate processings are registered in advance in a processing sequence order. Here, the contents of respective processings also include a predetermined event, estimated to change the internal pressure of the chamber 20 to a level out of the prescribed range, such as, for example, “gas supply switching,” “the gas discharge switching,” or “cup switching” as described above.

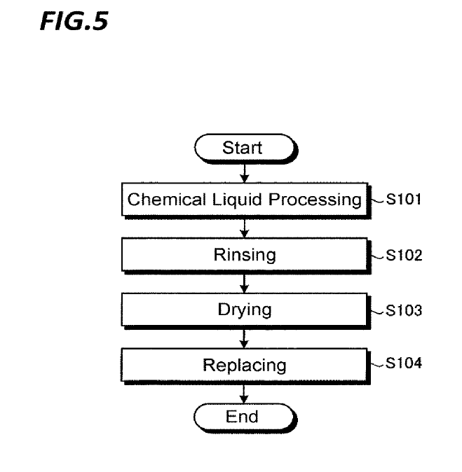

Here, descriptions will be made on a processing order of a series of substrate processings controlled by the controller 18 and executed in the processing unit 16 with reference to FIG. 5. FIG. 5 is a flowchart illustrating a processing order of a series of substrate processings executed in the processing unit 16.

As illustrated in FIG. 5, a chemical liquid processing (step S101), a rinsing process (step S102), a drying process (step S103), and a replacing process (step S104) are executed in this order in the processing unit 16.

The chemical liquid processing is to supply DHF to a wafer W, and the rinsing process is to supply DIW to the wafer W so as to rinse out the DHF from the wafer W. The drying process is to remove the DIW from the wafer W so as to dry the wafer W, and the replacing process is to replace the wafer W within the chamber 20.

Further, the above-mentioned events such as, for example, “gas supply switching,” “gas discharge switching,” and “cup switching,” are executed at least at the time of transition of the substrate processings from the rinsing process to the drying process, i.e., between step S102 and step S103.

Returning to FIG. 4, descriptions will be made on the case in which the controller 18 functions as the substrate processing execution unit 18a. With respect each processing to be executed from now based on the recipe information 19a, the controller 18 notifies the part of the damper adjustment unit 18b, which functions as the switching unit 18c, of the processing contents whenever the processing is executed. The notification contains an identifier (ID) for identifying each processing.

Also, when functioning as the damper adjustment unit 18b, the controller 18 performs the overall control related to the control of the opening degree of the damper 80. In addition, when functioning as the switching unit 18c, the controller 18 receives a notification from the part that functions as the substrate processing execution unit 18a and, based on the contents of the notification, the controller 18 switches the control of the opening degree of the damper 80 between the feedback control and the non-feedback control.

Specifically, when functioning as the switching unit 18c, the controller 18 cancels the control of the opening degree of the damper 80 by the normally performed feedback control when the processing contents indicated by the received notification correspond to an event that is estimated to change the internal pressure of the chamber 20 to a level out of the prescribed range.

Then, for a predetermined period of time from the occurrence of such an event, the non-feedback control is performed instead of the feedback control so as to control the opening degree of the damper 80 based on a prescribed control value. When the predetermined period of non-feedback control is terminated, the controller 18 returns the control of the opening degree of the damper 80 to the feedback control.

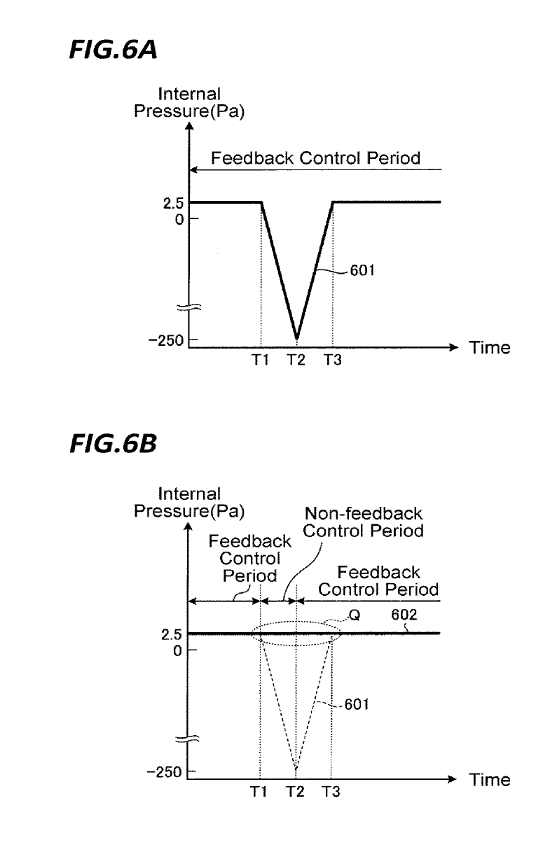

Descriptions will be made in more detail on the case where the controller 18 functions as the switching unit 18c with reference to FIGS. 6A and 6B. FIGS. 6A and 6B are explanatory views (Part 1 and Part 2) illustrating the case where the controller 18 functions as the switching unit 18c. FIG. 6A illustrates a conventional case only based on a feedback control.

Each drawing to be referred to following FIGS. 6A and 6B may represent a change in the internal pressure of the chamber 20 or the opening degree of the damper 80 as waveforms, in which the waveforms will be mainly represented as triangular or rectangular waves. However, this is merely for the convenience of description, and is not intended to represent the behavior of the damper 80 or a change in the internal pressure of the chamber 20 which follows the behavior, in a limited manner.

As the premise for the following description, it is assumed that the target value of the internal pressure of the chamber 20 to be maintained is 2.5 Pa in the present exemplary embodiment.

As indicated as “Feedback Control Period” in FIG. 6A, according to the prior art, in which the opening degree of the damper 80 is controlled by the feedback control throughout the substrate processings, for example, from time T1 to time T3, a waveform 601 indicating a change in the internal pressure may occasionally vibrate sharply towards the negative pressure side, even reaching a value of −250 Pa. This is because a sharp change may not be perfectly handled under the feedback control.

In this case, at least during the time period from T1 to from T3, the inside of the chamber 20 is in the negative pressure state, which is undesirable in preventing particles from adhering to the wafer W. By the way, the exemplary waveform 601 illustrated in FIG. 6A is likely to appear, for example, at the time of “gas supply switching” as described above.

Thus, as illustrated by the waveform 602 in FIG. 6B, the present exemplary embodiment is adapted to perform switching between a feedback control period and a non-feedback control period so as to eliminate an undershoot portion of the waveform 601 (see the portion surrounded by a closed curve Q indicated by a dotted line), thereby maintaining the internal pressure at 2.5 Pa.

Specifically, when functioning as the switching unit 18c, the controller 18 determines whether a processing to be performed from now is a predetermined event that is estimated to change the internal pressure to a level out of the prescribed range, based on the ID contained in the notification received from the part that functions as the substrate processing execution unit 18a. When it is determined the processing to be performed from now is the predetermined event, the controller 18 performs a non-feedback control that controls the opening degree of the damper 80 for a predetermined period of time from the occurrence of the event.

Referring to the example illustrated in FIG. 6B, the controller 18 handles the period, for example, between time T1 at which the target event occurs and time T2 at which the internal pressure indicates a minimum value as a non-feedback control period, and performs a non-feedback control that controls the opening degree of the damper 80.

In addition, a control value such as, for example, an opening degree or a maintained time of the opening degree during the “non-feedback control period,” is registered in advance as control value information 19b to be associated with each predetermined event and stored in the storage unit 19 of the control device 4 (see FIG. 4). Each control value included in the control value information 19b is derived and determined in advance through a test, for example.

Returning to FIG. 4, descriptions will be made on the case where the controller 18 functions as a feedback controller 18d. When functioning as the feedback controller 18d, the controller 18 performs a feedback control that controls the opening degree of the damper 80 based on the measurement result of the measuring unit 90 configured to measure the internal pressure of the chamber 20 in the processing unit 16 so as to maintain the internal pressure within the prescribed range.

Also, when functioning as a non-feedback controller 18e, the controller 18 performs a non-feedback control that controls the opening degree of the damper 80 based on a predetermined control value contained in the control value information 19b.

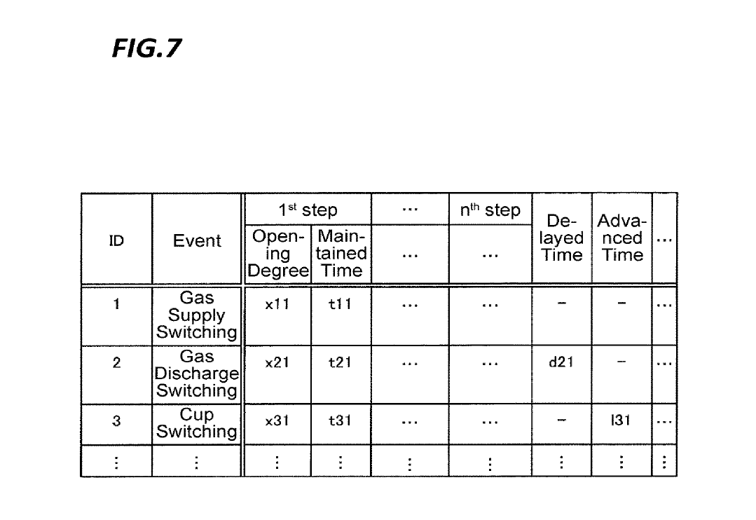

Next, the contents of the control value information 19b will be described with reference to FIG. 7. FIG. 7 illustrates an example of the control value information 19b.

As described above, the control value information 19b is information in which various control values in the non-feedback control period are associated with predetermined events, respectively. Specifically, as illustrated in FIG. 7, the information is configured to include, for example, items “ID,” “Event,” “Opening Degree,” “Maintained Time,” “Delayed Time,” and “Advanced Time.” The items “Opening Degree” and “Maintained Time” may be handled as one set and divisionally registered over a plurality steps from the 1^{st} step to the n^{th} step.

The item “ID” is an item in which an ID for identifying a predetermined event, estimated to change the internal pressure of the chamber 20 to a level out of the prescribed range, is stored. The item “Event” is an item in which specific event contents are stored.

The item “Opening Degree” is an item in which the opening degree of the damper 80 is stored. The item “Maintained Time” is an item in which the time for maintaining the opening degree stored in the item “Opening Degree” is stored. The item “Delayed Time” is an item in which the time for delaying starting of control of the opening degree by the non-feedback control is stored. The item “Advanced Time” is an item in which the time for advancing starting of control of the opening degree by the non-feedback control is stored.

Meanwhile, according to the example illustrated in FIG. 7, for the sake of convenience, “x11” and “t11” are respectively stored as the opening degree and the maintained time at the time of “gas supply switching.” Also, “x21,” “t21,” and “d21” are respectively stored as the opening degree, the maintained time, and the delayed time at the time of “gas discharge switching.” Further, “x31,” “t31,” and “l31” are respectively stored as the opening degree, the maintained time, and the advanced time at the time of “cup switching.”

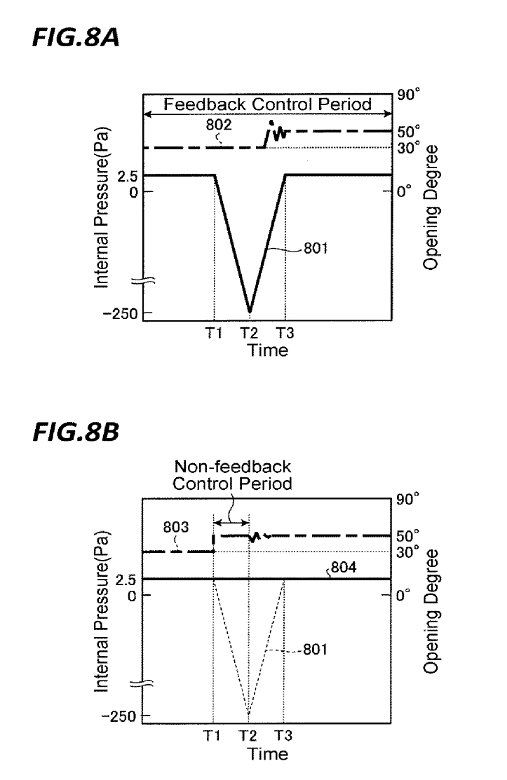

Based on the control value information 19b, the controller 18 performs the non-feedback control on the opening degree of the damper 80. Then, an example of the non-feedback control performed by the controller 18 will be described with reference to FIGS. 8A and 8B.

FIG. 8A illustrates a change in the internal pressure and the opening degree under a conventional feedback control. FIG. 8B illustrates an exemplary non-feedback control performed by the controller 18. In addition, FIGS. 8A and 8B are represented as biaxial graphs representing the internal pressure and the opening degree on their respective vertical axes, in which the waveform of the internal pressure is indicated by a solid line and the waveform of the opening degree is indicated by an alternate long and short dash line. Also, the examples illustrated in FIGS. 8A and 8B correspond to FIGS. 6A and 6B, respectively, and represent the internal pressure and the opening degree at the time of a “gas supply switching” event.

As illustrated by a waveform 801 in FIG. 8A, in the case where the opening degree of the damper 80 is controlled only by the feedback control, an undershoot reaching −250 Pa will occur during the period of time T1 to time T3 at the time of “gas supply switching.” Further, as illustrated by a waveform 802, the opening degree in this event will be maintained at 30° even after time T2, gradually rise between time T2 and time T3, and converge to 50° after time T3.

In this case, the controller 18 of the present exemplary embodiment immediately controls the opening degree at time T1 from 30° to 50°, as illustrated by a waveform 803. Then, the controller 18 switches the control of the opening during T2 from the non-feedback control to the feedback control, and thereafter allows a change in the internal pressure to converge by the feedback control (see the waveform 804 in the drawing).

By doing so, it is possible to eliminate the negative pressure condition in the chamber 20, which would have occurred in the prior art during the period of time T1 to time T3. In other words, it is possible to properly maintain the internal pressure of the chamber 20. Here, it is exemplified that the waveform oscillates towards the negative pressure side. However, when the waveform oscillates towards the positive pressure side, i.e., when an overshoot occurs, it is still possible to determine and apply an appropriate control value.

While FIG. 8B illustrates an example in which the opening degree is controlled to a predetermined level (50°) immediately at a single step, the non-feedback control by the controller 18 is not limited thereto when it is based on the control value information 19b. For example, in the case where control values are divisionally registered over a plurality of steps from the 1^{st} step to n^{th} step in the control value information 19b (see FIG. 7), the controller 18 controls the opening degree step by step accordingly.

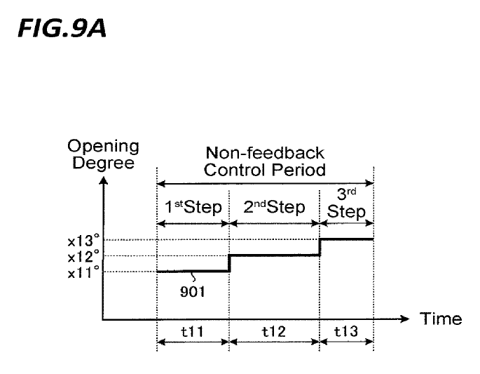

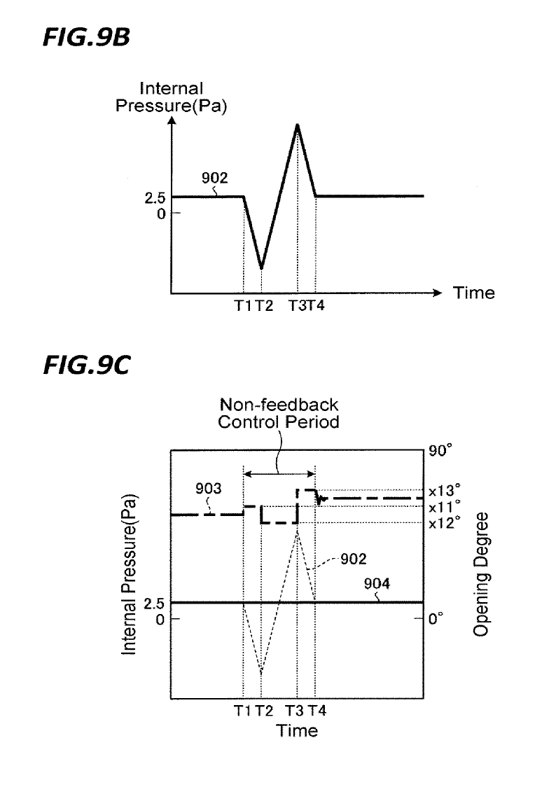

FIGS. 9A to 9C are explanatory views (Part 1 to Part 3) illustrating a case where the controller 18 controls the opening degree step by step.

For example, when the opening degree and the maintained time are divisionally registered in the first to the third steps in the control value information 19b, the controller 18 controls the opening degree at divided three steps so as to change the opening degree step by step as indicated by the waveform 901 in FIG. 9A.

In the example illustrated in FIG. 9A, the opening degrees having a relationship represented as x11<x12<x13 are registered in this order in the control value information 19b as the opening degrees at the first to third steps, respectively. In addition, the maintained times t11, t12, and t13 are registered in this order as the maintained times at the first to third steps, respectively.

While FIG. 9A illustrates an example in which the opening degree increases step by step. However, depending on a pattern appearing with a change in the internal pressure, the opening degree may decrease, for example, in a relationship represented as x11>x12>x13.

Of course, the opening degree may be adapted to increase and then decrease step by step. For example, it is assumed that between time T1 and time T4, there is a waveform 902 representing a pressure change in which an undershoot and an overshoot occur successively, as illustrated in FIG. 9B.

In this case, the controller 18, may maintain the internal pressure by increasing and decreasing the opening degree step by step, for example, as illustrated in FIG. 9C (see the waveforms 903 and 904 in the drawings).

Specifically, the opening degrees with a relationship represented as x12<x11<x13 are registered as the respective opening degrees at the first to third steps in the order of x11, x12, and x13 in the control value information 19b. Further, the maintained time at the first step is made to correspond to time T1 to time T2 during which the waveform 902 falls. The maintained time at the second step is made to correspond to T2-T3 during which the waveform 902 rises. The maintained time at the third step is made to correspond to time T3 to time T4 during which the waveform 902 falls again.

By following such control value information 19b, the controller 18 is able to increase and decrease the opening degree step by step as represented by the waveform 903.

By enabling such a control to change the opening degree step by step, it is possible to handle a sharp pressure change that tends to occur in different patterns. In other words, the internal pressure of the chamber 20 may be maintained properly.

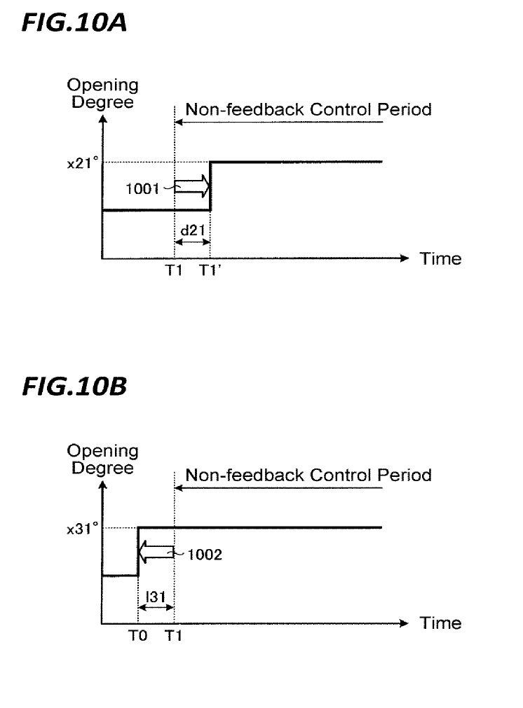

Next, descriptions will be made on a case where the controller 18 delays or advances the starting of control of the opening degree by a non-feedback control based on the control value information 19b with reference to FIGS. 10A and 10B. FIG. 10A illustrates a case where the controller 18 delays starting of control of the opening degree. FIG. 10B illustrates a case where the controller 18 advances starting of control of the opening degree.

Since the delayed time or the advanced time is registered in the control value information 19b (see FIG. 7), the controller 18 is able to delay or advance starting of control of the opening by the non-feedback control.

With respect to a predetermined event in the control value information 19b, it is assumed that that a delayed time of “d21” has been registered. In this case, as illustrated in FIG. 10A, the controller 18 starts to control the opening degree from time T1′ by delayed time T1, which is the original non-feedback control starting time, by d21 (see the arrow 1001 in the drawing).

With respect to a predetermined event in the control value information 19b, it is also assumed that an advanced time of l31 has been registered. In that event, as illustrated in FIG. 10B, the controller 18 starts to control the opening degree from time T0 earlier than time T1, which is the original non-feedback control time, by l31 (see the arrow 1002 in the drawing).

In the case of advancing the starting of control of the opening degree, for example, when the part that functions as the switching unit 18c was notified of an event immediately preceding an event to be switched to the non-feedback control by the part that functions as the substrate processing execution unit 18a, advancing the starting of control of the opening degree may be implemented by driving the time when the immediately preceding event is completed and advancing the starting of control of the opening degree with reference to the completed time.

By delaying or advancing starting of control of the opening degree by the non-feedback control in this way, for example, a time lag caused by a mechanical factor may be eliminated. In other words, since it is possible to precisely handle a change in internal pressure, the internal pressure of the chamber 20 may be properly maintained.

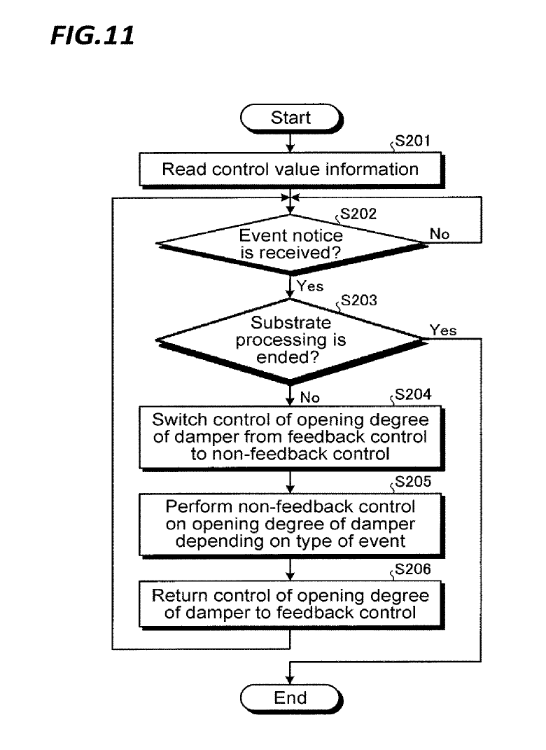

Next, descriptions will be made on a processing order in the case where the controller 18 functions as the damper adjustment unit 18b with reference to FIG. 11.

FIG. 11 is a flowchart illustrating a processing order of processings executed in case where the controller 18 functions as the damper adjustment unit 18b. First, as an initial processing, the control value information 19b is read (step S201). Then, the controller 18 determines whether there has been an event notification from the part executing a series of substrate processings (step S202).

Here, when there is no event notification (step S202, No), step S202 is repeated until there is an event notification. Further, when there is an event notification (step S202, Yes), the controller determines whether the event notification is the end of a substrate processing (step S203).

Here, when the event notification is not the end of a substrate processing (step S203, No), the controller 18 switches the control of the opening degree of the damper 80 from the feedback control to the non-feedback control (step S204).

Then, the controller 18 performs the non-feedback control on the opening degree of the damper 80 depending on the type of the event (step S205).

When the non-feedback control on the target event is completed, the controller 18 returns the control of the opening degree of the damper 80 to the feedback control (step S206), and then repeats the processings from step S202.

In addition, when it is determined that it is the end of a substrate processing at step S203 (step S203, Yes), the processing is ended.

As described above, the substrate processing system 1 according to the present exemplary embodiment (corresponding to an example of the “substrate processing apparatus”) is provided with a chamber 20, an FFU 21, a CDA gas supply unit 24 (corresponding to an example of the gas supply unit), a gas discharge port 52 (corresponding to an example of the gas discharge port), a damper 80 (corresponding to an example of the adjustment mechanism), a measuring unit 90, and a controller 18.

The chamber 20 accommodates a processing target wafer W. The FFU 21 and CDA gas supply unit 24 supply a gas to the inside of the chamber 20. The gas discharge port 52 exhausts the inside of the chamber 20. The damper 80 controls the exhaust amount discharged from the gas discharge port 52. The measuring unit measures the internal pressure of the chamber 20. The controller 18 executes a series of substrate processings according to the recipe information 19a indicating contents of the substrate processing.

Also, the controller 18 performs a feedback control that controls the opening degree of the damper 80 so as to maintain the internal pressure of the chamber 20 within the prescribed range based on the measurement result of the measuring unit 90, and in the case where a predetermined event, estimated to change the internal pressure of the chamber 20 to a level out of the prescribed range, occurs, the controller 18 performs a non-feedback control that controls the opening degree of the damper 80 based on a predetermined control value, instead of the feedback control.

Thus, the substrate processing system 1 according to the present exemplary embodiment enables the internal pressure of the chamber 20 to be properly maintained.

Although DHF is exemplified as a chemical liquid in the above-described exemplary embodiments, other examples of the chemical liquid include SC1, SC2, SPM, resist, developer, silylating agent, and ozone water.

Further, the rinse liquid is not limited to DIW described above. For example, when the rinsing process includes supplying DIW to the wafer W and replacing DIW on the wafer W with IPA, IPA is also included in the rinse liquid.

Also, although the above-described exemplary embodiment exemplifies “gas supply switching,” “gas discharge switching,” and “cup switching” as the predetermined events, estimated to change the internal pressure of the chamber 20 to a level out of the prescribed range, but the predetermined events are not limited thereto.

For example, at the time of transition from the drying process to the replacing process, during which a shutter (not illustrated) of the chamber 20 is opened and closed so as to replace a wafer W, the control of the opening degree may be performed by the non-feedback control.

Also, in the above-described exemplary embodiment, the part of the controller 18, which functions as the switching unit 18c, is described as an example in which each processing process to be performed from now is identified based on a notification received from the part that functions as the substrate processing execution unit 18. However, the part of the controller 18, which functions as the switching unit 18c, may directly refer to the recipe information 19a. Further, the controller 18 may be configured in a form in which the substrate processing execution unit 18a and the damper adjustment unit 18b are integrated therein so that the controller 18 may integrally execute the substrate processings and the damper adjustment while referring to the recipe information 19a.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate processing apparatus comprising:
a chamber configured to accommodate a processing target substrate therein;
a gas supply unit configured to supply a gas into the chamber;
a gas discharge port configured to exhaust the chamber;
an adjustment mechanism configured to adjust an exhaust amount discharged from the gas discharge port;
a measuring unit configured to measure an internal pressure of the chamber; and
a controller configured to execute a series of substrate processings according to recipe information indicating contents of substrate processings,
wherein the controller performs a feedback control that controls an opening degree of the adjustment mechanism to maintain the internal pressure within a prescribed range based on a measurement result from the measuring unit, and, when a predetermined event, estimated to change the internal pressure to a level out of the prescribed range, occurs, the controller switches the feedback control to a non-feedback control that controls the opening degree based on a prescribed control value.

2. The substrate processing apparatus of claim 1, wherein the controller performs the non-feedback control when an event, estimated to change the internal pressure to a negative pressure out of the prescribed range, occurs.

3. The substrate processing apparatus of claim 2, wherein the series of substrate processings include a chemical liquid processing for supplying a chemical liquid to the substrate, a rinsing process for supplying a rinse liquid to the substrate after the chemical liquid processing, and a drying process for drying the substrate after the rinsing process,
wherein the gas supply unit further includes:
a first gas supply unit configured to supply a first gas; and
a second gas supply unit configured to supply a second gas at the drying process, and
wherein, when switching from the first gas supply unit to the second gas supply unit is executed, the controller switches the feedback control to the non-feedback control.

4. The substrate processing apparatus of claim 2, wherein the series of substrate processings include a chemical liquid processing for supplying a chemical liquid to the substrate, a rinsing process for supplying a rinse liquid after the chemical liquid processing, and a drying process for drying the substrate after the rinsing process,
the gas discharge port connects gas discharge paths of a plurality of systems according to respective processings in the substrate processings, and
the controller switches the feedback control to the non-feedback control when switching between the gas discharge paths is executed at the time of transition of each processing of the substrate processings.

5. The substrate processing apparatus of claim 4, wherein the gas discharge paths include a first gas discharge path in the rinsing process and a second gas discharge path in the drying process.

6. The substrate processing apparatus of claim 2, wherein the series of substrate processings include a chemical liquid processing for supplying a chemical liquid to the substrate, a rinsing process for supplying a rinse liquid after the chemical liquid processing, and a drying process for drying the substrate after the rinsing process,
wherein the substrate processing apparatus further comprises:
a substrate holding mechanism placed within the chamber and configured to hold and rotate the substrate; and
a plurality of recovery cups arranged concentrically to a rotation center of the substrate rotated by the substrate holding mechanism and configured to recover discharged liquid in the respective processings of the substrate processings, and
wherein, when switching between the recovery cups is executed at the time of transition of each respective processing of the substrate processings, the controller switches the feedback control to the non-feedback control.

7. The substrate processing apparatus of claim 6, wherein the recovery cups include a first recovery cup configured to recover discharged liquid in the rinsing process and a second recovery cup configured to recover discharged liquid in the drying process.

8. The substrate processing apparatus of claim 1, wherein the control value includes a control value of a maintained time indicating a time for maintaining the opening degree, and the controller maintains the opening degree based on the control value of the maintained time.

9. The substrate processing apparatus of claim 8, wherein when the maintained time lapses, the controller returns the control of the opening degree from the non-feedback control to the feedback control.

10. The substrate processing apparatus of claim 8, wherein the control value includes a step designation control value for changing the opening degree and the maintained time step by step, and
the controller changes the opening degree and the maintained time step by step based on the step designation control value.

11. The substrate processing apparatus of claim 8, wherein the control value includes a control value of a delayed time indicating a time for delaying starting of control of the opening degree, and
the controller delays the starting of control of the opening degree based on the control value of the delayed time.

12. The substrate processing apparatus of claim 11, wherein the control value includes a control value of an advanced time indicating a time for advancing the starting of control of the opening degree, and
the controller advances the starting of control of the opening based on the control value of the preceding time.

13. A substrate processing method comprising:
a control process for executing a series of substrate processings according to recipe information indicating contents of substrate processings using a substrate processing apparatus including a chamber configured to accommodate a processing target substrate, a gas supply unit configured to supply a gas into the chamber, a gas discharge port configured to exhaust the chamber, an adjustment mechanism configured to control an exhaust amount discharged through the gas discharge port, and a measuring unit configured to measure an internal pressure of the chamber,
wherein the control process executes a feedback control that controls an opening degree of the adjustment mechanism to maintain the internal pressure within a prescribed range based on a measurement result from the measuring unit; and, when a predetermined event, estimated to change the internal pressure to a level out of the prescribed range, occurs, the control process performs switches the feedback control into a non-feedback control that controls the opening degree based on a prescribed control value.
